(19) United States
(12) Patent Application Publication
(10) Pub. No.: US 2026/0165134 A1
(43) Pub. Date: Jun. 11, 2026

(54) RING STRUCTURE FOR INTERCONNECT STRUCTURES AND METHODS OF FORMING THE SAME

(71) Applicant: Taiwan Semiconductor Manufacturing Company Limited, Hsinchu (TW)

(72) Inventors: Ping-Yin Hsieh, Hsinchu City (TW); Chih-Wei Wu, Zhuangwei Township (TW); Ying-Ching Shih, Hsinchu City (TW)

(21) Appl. No.: 18/969,666

(22) Filed: Dec. 5, 2024

(51) Int. Cl. H01L 23/58; H01L 21/768; H01L 23/00

(52) U.S. Cl. CPC H10W 42/00; H10W 20/032; H10W 72/01235; H10W 72/01255; H10W 72/07236; H10W 72/222; H10W 72/252; H10W 72/29; H10W 90/724

(57) ABSTRACT

A semiconductor device and methods for forming the same. In some embodiments, the semiconductor device includes a first interconnect structure on a first semiconductor substrate, wherein the first interconnect structure includes a first conductive metal material and a ring structure. The ring structure may extend above the first conductive metal material or surround the first conductive metal material. In some embodiments, the semiconductor device may further include a second conductive metal material and, optionally, a third conductive metal material. The ring structure may partially surround a solder material formed above the first conductive material.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

A package assembly may include an interposer module mounted on a package substrate or interposer. The interposer module may include one or more semiconductor dies connected to an interposer or substrate dielectric by interconnect structures (e.g., microbumps). In some instances, and in particular in instances of fine pitch interconnect structures, sidewall wetting of solder may cause solder to bridge between adjacent interconnect structures. This causes unintended electrical connections or electrical shorts. Mitigating against the sidewall wetting of solder is desired.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example vertical cross-sectional view of a substrate and a passivation layer in an intermediate interconnect structure according to various embodiments of the present disclosure.

FIG. 2 is an example vertical cross-sectional view of patterning a passivation layer in an intermediate interconnect structure according to various embodiments of the present disclosure.

FIG. 3 is an example vertical cross-sectional view of depositing a seed layer above the passivation layer in an intermediate interconnect structure according to various embodiments of the present disclosure.

FIG. 4 is an example vertical cross-sectional view of forming a cavity in the passivation layer in an intermediate interconnect structure according to various embodiments of the present disclosure.

FIG. 5 is an example vertical cross-sectional view of forming an under-bump metallization layer in an intermediate interconnect structure according to various embodiments of the present disclosure.

FIG. 6 is an example vertical cross-sectional view of forming a seed layer in an intermediate interconnect structure according to various embodiments of the present disclosure.

FIG. 7 is an example vertical cross-sectional view of forming a photoresist layer in an intermediate interconnect structure according to various embodiments of the present disclosure.

FIG. 8 is an example vertical cross-sectional view of patterning a photoresist layer in an intermediate interconnect structure according to various embodiments of the present disclosure.

FIG. 9 is an example vertical cross-sectional view of plating a conductive metal material in an intermediate interconnect structure according to various embodiments of the present disclosure.

FIG. 10 is an example vertical cross-sectional view of removing a photoresist layer in an intermediate interconnect structure according to various embodiments of the present disclosure.

FIG. 11 is an example vertical cross-sectional view of forming a photoresist layer in an intermediate interconnect structure according to various embodiments of the present disclosure.

FIG. 12 is an example vertical cross-sectional view of patterning a photoresist layer in an intermediate interconnect structure according to various embodiments of the present disclosure.

FIG. 13 is an example vertical cross-sectional view of plating a ring structure in an intermediate interconnect structure according to various embodiments of the present disclosure.

FIG. 14 is an example vertical cross-sectional view of removing a photoresist layer in an intermediate interconnect structure according to various embodiments of the present disclosure.

FIG. 15 is an example vertical cross-sectional view of forming a photoresist layer in an intermediate interconnect structure according to various embodiments of the present disclosure.

FIG. 16 is an example vertical cross-sectional view of patterning a photoresist layer in an intermediate interconnect structure according to various embodiments of the present disclosure.

FIG. 17 is an example vertical cross-sectional view of depositing a solder material in an intermediate interconnect structure according to various embodiments of the present disclosure.

FIG. 18 is an example vertical cross-sectional view of removing a photoresist layer in an in an interconnect structure according to various embodiments of the present disclosure.

FIGS. 19A through 19E are example vertical cross-sectional views of alternative embodiments of the interconnect structure according to various embodiments of the present disclosure.

FIGS. 20A through 20E are example vertical cross-sectional views of alternative embodiments of the ring structure according to various embodiments of the present disclosure.

FIG. 21 is an example top view of the interconnect structure and ring structure according to various embodiments of the present disclosure.

FIGS. 22A through 22C are example vertical cross-sectional views of interconnect structures with a bottom bump structure and top bump structure according to various embodiments of the present disclosure.

FIG. 23 is a flowchart illustrating a method of forming an interconnect structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Microbumps are interconnect structures that may connect a semiconductor die to a variety of surfaces and substrates, such as a silicon substrate, redistribution layer, chip on a wafer, or other appropriate substrates. In general, interconnect structures such as microbumps, may include a bottom bump and an upper bump. The bottom bump (e.g., on the surface or substrate) may include a copper scheme, a copper/nickel/copper/solder scheme, or a copper/nickel/solder scheme. The top bump (e.g., on the semiconductor die) may include a copper/nickel/copper/solder scheme.

A mass reflow process may be used to bond the top bump to the bottom bump. After the initial interconnect structures (also referred to as bumps, bump structures, or bump interconnect structures) may be formed on the surface or substrate and the semiconductor die, the interconnect structures may undergo a reflow process. The reflow process includes heating the semiconductor structure including the interconnect structures in a reflow oven to uniformly heat and melt the solder material contained in one of the top bump or bottom bump. As the solder melts, the interconnect structures are shaped into spheres due to surface tension. The semiconductor structure is then gradually cooled to solidify the solder re-flowed in the interconnect structures.

In instances in which the interconnect structures are closely spaced together (e.g., have a fine pitch), sidewall wetting may cause a bump bridge defect to form between adjacent interconnect structures during the reflow process. The wettability of the solder when re-flowed may cause the molten solder to flow between adjacent interconnect structures rather than between corresponding top bumps and bottom bumps. This may not only cause an electrical short between adjacent interconnect structures, but prevent an adequate electrical connection between a corresponding top bump and bottom bump because there is an insufficient volume of solder due to the migration of the solder to the adjacent interconnect structure. The bump bridge defects may cause a failure of a reliability test such as a high temperature storage (HTS) test. Thus, the interconnect structures may make it difficult to increase a pitch (e.g., interconnect structure pitch, distance between center-to-center of interconnect structures) because an increased pitch (e.g., fine pitch bump dense area) may exacerbate the probability of bump bridge defects.

Additionally, during the reflow process, the interconnect structures may cause bump tilting due to non-uniform heating, surface tension imbalances, or misalignment. The bump tilting may cause poor electrical connection through the interconnect structures between the substrate and semiconductor dies. Additionally, the bump tilting may decrease mechanical strength of the interconnect structures resulting in overall mechanical failure of the semiconductor device. The bump tilting therefore compromises the performance and reliability of the semiconductor device.

Various embodiments of the present disclosure relate to a semiconductor device that includes a ring structure to prevent bump bridging and bump tilting. In some embodiments, the semiconductor device includes a first conductive metal material and a ring structure extending above the first conductive metal material. In some embodiments, the semiconductor device further includes a second conductive metal material, a third conductive metal material, and/or a fourth conductive metal material. Additionally, the semiconductor device may include a solder material. In an alternative embodiment, the semiconductor device includes a first conductive metal material and a ring structure that surrounds the first conductive metal material. In some embodiments, the semiconductor device further includes a second conductive metal material and/or a third conductive metal material and the ring structure also surrounds the second conductive metal material and/or the third conductive metal material. Additionally, the semiconductor device may include a solder portion. surface module inspection tool may include a laser, a detector, and a signal analysis module.

In an alternative embodiment, a method to form a semiconductor device includes a photoresist layer is patterned to form a interconnect structures cavity. A first conductive metal material is plated within the interconnect structures cavity and the photoresist layer is further patterned to form a ring cavity. A ring conductive metal material is plated in the ring cavity and the photoresist layer is removed.

Various embodiments disclosed herein may provide various advantages and improvements. For example, various embodiments disclosed herein may include a ring structure that surrounds a portion of the solder. Therefore, various embodiments disclosed herein may prevent bump bridging by ensuring the electrical isolation of individual interconnect structures from one another during the reflow process. By preventing bump bridging, various embodiments improve reliability tests of the semiconductor device, such as a HTS test. Additionally, various embodiments disclosed herein prevent bump tilting by ensuring the interconnect structures form perpendicular to the substrate or interposer during the reflow process. By preventing bump tilting, various embodiments improve mechanical strength of the interconnect structures to reduce mechanical failures therefore improving performance and reliability of the semiconductor device. Various embodiments disclosed herein may further improve electrical connection between the substrate and the semiconductor dies through the interconnect structures by improving the interconnect structures formed during the reflow process.

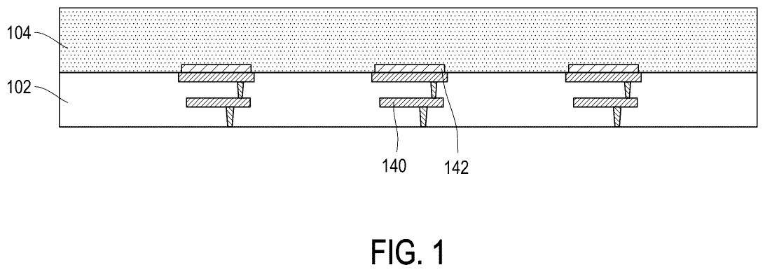

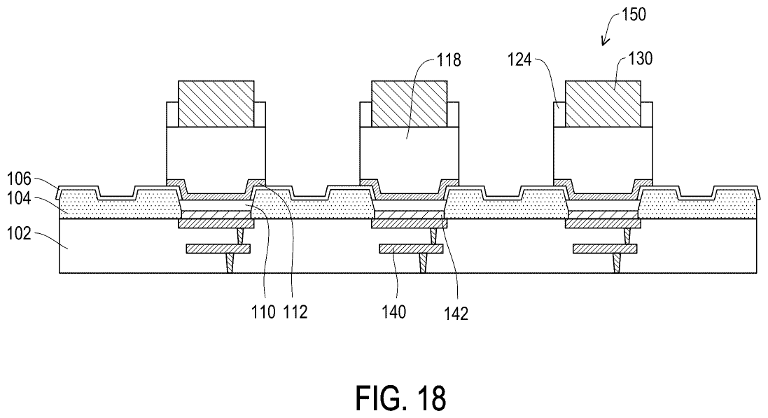

FIGS. 1 through 17 illustrate various intermediate structures of forming a semiconductor device with an interconnect structure scheme according to various embodiments. FIGS. 18-21C illustrate various embodiments interconnect structures. FIG. 1 is a vertical cross-sectional view of a substrate 102 and a passivation layer 104. The substrate 102 may include any substrate that may support a package assembly. For example, the substrate 102 may include a system on integrated substrate (SoIS), a printed circuit board (PCB), a redistribution layer (RDL), a silicon substrate, or appropriate alternative substrates.

The substrate 102 may include metal interconnects 140 (e.g., metal traces and metal vias) formed therein to facilitate electrical connections to and from electrical devices. The substrate may be a dielectric material such as silicon dioxide, silicon nitride, aluminum oxide, or other appropriate materials. The substrate 102 may also include substrate bonding pads 142 (e.g., package substrate contact pads). The bonding pads 142 may be composed of a conductive metal material such as copper, silver, chromium, nickel, tin, tungsten, titanium, gold, copper alloy, or other suitable conductive metal materials or alloys. The substrate bonding pads 142 may be used to provide an electrical connection to semiconductor devices (e.g., semiconductor dies) that are mounted on the substrate 102.

The passivation layer 104 may be formed of a dielectric material such as silicon dioxide, silicon nitride, aluminum oxide, or other appropriate materials. The passivation layer 104 may act as a barrier to protect the substrate 102 and bonding pads 142 from corrosion or contaminates (e.g., dust particles or chemicals). Additionally, the passivation layer 104 may reduce the chemical reactivity of the surface of the substrate 102 and/or bonding pads 142 therefore maintaining the integrity of the material over time and reduce surface states and defects therefore improving performance of the package assembly. The passivation layer 104 may be formed by spin coating and drying of the respective dielectric polymer material. The thickness of the passivation layer 104 may be in a range from 2 microns to 40 microns, such as from 4 microns to 20 microns.

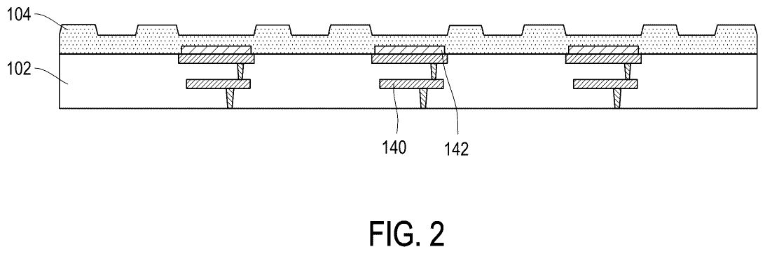

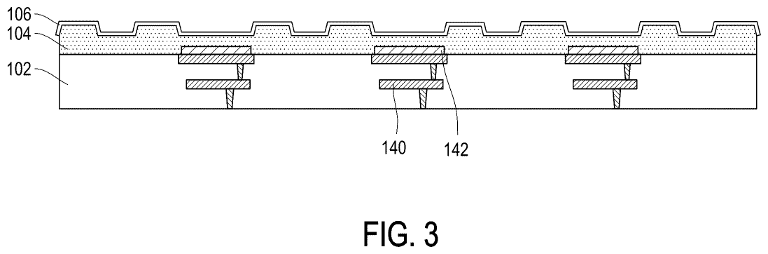

FIG. 2 is a vertical cross-sectional view of patterning the passivation layer 104 and FIG. 3 is a vertical cross-sectional view of depositing a dielectric material 106 above the passivation layer 104 in an intermediate interconnect structure. The passivation layer 104 may be patterned, for example, by applying and patterning a respective photoresist layer thereabove, and by transferring the pattern in the photoresist layer into the passivation layer 104 using an etch process such as an anisotropic etch process. The photoresist layer may be subsequently removed, for example, by ashing. The passivation layer 104 may be patterned to prepare the surface for the dielectric material 106. The dielectric material 106 may include a dielectric polymer material such as polyimide (PI), benzocyclobutene (BCB), or polybenzobisoxazole (PBO), or other appropriate organic or inorganic dielectric materials. The dielectric material 106 may act as a stress buffer therefore reducing the thermal and mechanical stress on the passivation layer 104 and substrate 102 further preventing cracking and other damage. Additionally, the dielectric layer 106 may function as an additional protective barrier against moisture, contaminants, and environmental factors from damaging the substrate 102 and bonding pads 142 located underneath. The dielectric layer 106 may also provide electrical insulation, flexibility to accommodate expansion and contraction during temperature changes, and provides an adhesion layer between different layers in the package.

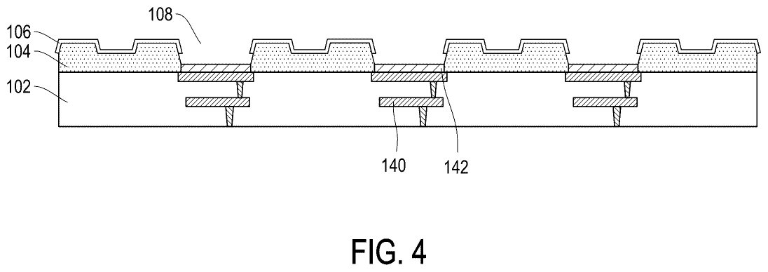

FIG. 4 is a vertical cross-sectional view of patterning the passivation layer 104 and the dielectric layer 106 to form a bump cavity 108 in an intermediate interconnect structure. The bump cavity 108 may expose the substrate bonding pads 142 to allow the subsequently formed interconnect structures to connect with the substrate bonding pads 142. An upper surface of the substrate bonding pads 142 may be exposed through the bump cavity 108. The bump cavities 108 may have a tapered sidewall so that a diameter of the bump cavities 108 (in the X-Y plane) may decrease in a direction toward the substrate bonding pad 142.

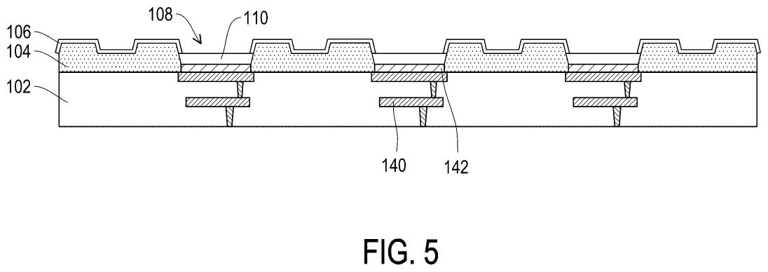

FIG. 5 is a vertical cross-sectional view of depositing a conductive metal material in the bump cavity 108 to form an under-bump metallization (UBM) structure 110 in an intermediate interconnect structure. Prior to depositing the conductive metal material, the bump cavity 108 may be cleaned using a chemical mechanical polishing (CMP) process or other appropriate processes. The cleaning process may remove oxides or other contaminates from the bump cavity 108. The UBM structure 110 may be formed of a conductive metal material such as copper, nickel, titanium, or other appropriate materials.

The conductive metal material may be deposited into the bump cavity 108 using physical vapor deposition (PVD), chemical vapor deposition (CVD), atomistic vapor deposition (AVD), or other appropriate deposition methods. In some embodiments, the UBM structure 110 may further be patterned or cleaned to achieve the desired shape and to smooth the top surface.

The UBM structure 110 may provide an electrical and mechanical connection to the substrate bonding pad 142 and interconnect structures 140. For example, the UBM structure 110 may ensure reliable signal transmission and support to the interconnect structures, therefore enhancing the structural integrity of the package. The UBM structure 110 also acts as barrier to prevent diffusion of materials that may potentially degrade the package performance. Overall, the UBM structure 110 may enhance the reliability by providing sufficient electrical and mechanical connections while maintaining the performance of the package by preventing material diffusion.

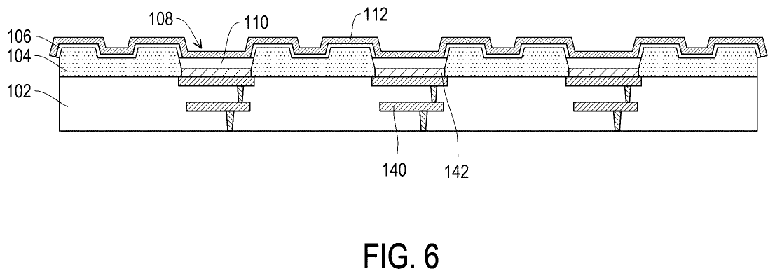

FIG. 6 is a vertical cross-sectional view of is depositing a seed layer 112 above the dielectric layer 106 and UBM structure 110 in an intermediate interconnect structure. The seed layer 112 may be deposited by PVD, AVD, CVD, or other appropriate deposition methods. In some embodiments, the seed layer 112 is formed of copper, titanium, nickel, gold, other appropriate metals, and combinations thereof. The seed layer 112 may provide a conductive base for electroplating conductive metals. Additionally, the seed layer 112 ensures adequate adhesion between the UBM structure 110 and the subsequently electroplated conductive metal materials. Further, the seed layer 112 may provide barrier properties to prevent diffusion of materials.

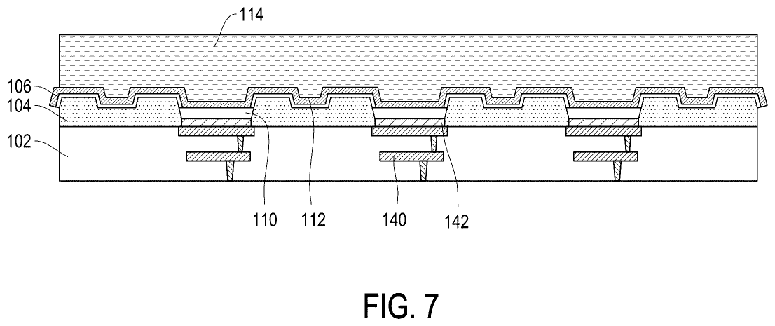

FIG. 7 is a vertical cross-sectional view of forming a photoresist layer 114 above the seed layer 112. The photoresist layer 114 is a light-sensitive material used in a photolithography process to form geometric patterns onto a surface. The photoresist layer 114 may be a positive photoresist layer where in the instance the photoresist layer is exposed to light, the photoresist layer 114 becomes soluble to allow the exposed areas to be washed away or a negative photoresist layer where in the instance the photoresist layer 114 is exposed to light, the photoresist layer 114 becomes insoluble and the unexposed areas are washed away. The photoresist layer 114 may be formed of a resin, photoactive compound, and a solvent and optionally dyes for visual inspection or anti-oxidizing agents to enhance stability.

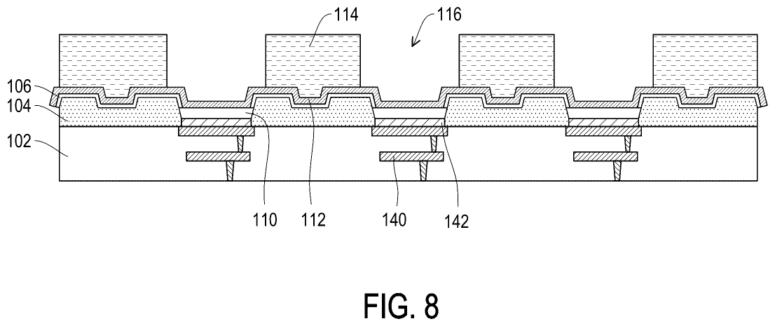

FIG. 8 is a vertical cross-sectional view of patterning and developing the photoresist layer 114 in an intermediate interconnect structure. Initially, the photoresist layer 114 may be exposed to light at a specific wavelength (e.g., UV light between 100 nm and 400 nm) through a mask with the desired pattern. In this embodiment and as shown in FIG. 8, the mask may include sections corresponding to the bump cavities 116 within the photoresist layer 114. The chemical structure of the photoresist layer 114 may be altered in areas exposed to the light beams. The structure may then be developed using a chemical solution which either removes the exposed or unexposed areas based on the type of photoresist material used. For example, a positive photoresist material will wash away the exposed areas while a negative photoresist material will wash away the unexposed areas. The resulting structure includes bump cavities 116 in the photoresist layer 114 exposing the seed layer 112 previously formed over the UBM structures 110.

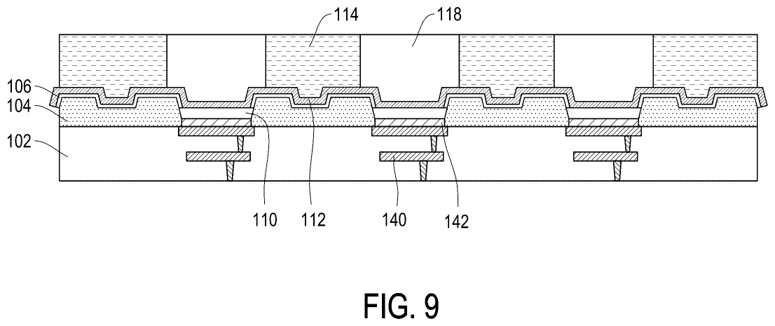

FIG. 9 is a vertical cross-sectional view of plating a first conductive metal material 118 in the bump cavities 116 in an intermediate interconnect structure. Initially, a thin layer of conductive metal material 118 may be deposited onto the seed layer 112. The conductive metal material 118 may be copper, nickel, titanium, tungsten, gold, silver, or other appropriate conductive metal materials. In some embodiments, the first conductive metal material 118 is chosen based on conductive properties therefore creating an appropriate electrical connection.

The initial thin layer provides a conductive surface for electroplating. The entire structure may then be submerged in an electrolyte bath containing a solution of high-texture material ions, such as copper ions or copper sulfate. An electrical current may be applied causing the high-texture material ions to migrate and deposit onto the thin layer forming a thicker high-texture material layer. After electroplating, the surface may undergo planarization by being polished using a chemical-mechanical polishing process to remove excess ions and achieve a smooth planar surface. The resulting structure includes a first conductive metal material 118 formed within the bump cavities 116.

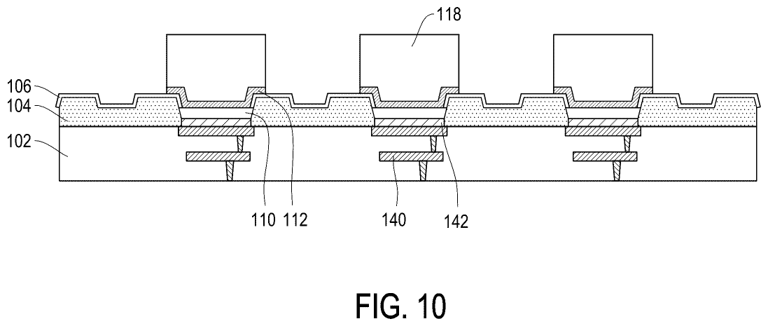

FIG. 10 is a vertical cross-sectional view of removing or stripping the photoresist layer 114 and a portion of the seed layer 112 leaving behind the first conductive metal material 118 in an intermediate interconnect structure. The photoresist layer 114 stripping process may include a wet stripping, a dry stripping, or a combination method. The wet stripping process may use a chemical solution of solvents and/or acids to dissolve and remove the photoresist layer 114. The dry stripping process may use a plasma, such as an oxygen plasma, of ionized gas to break down the photoresist layer 114. The plasma may react with the photoresist layer 114 to form a volatile compound that is then removed. Combination methods include wet stripping and dry stripping to ensure a complete removal by dissolving and breaking down the photoresist layer 114. Additionally, a portion of the seed layer 112 that is not located below the first conductive metal material 118 may be stripped. The resulting structure includes the first conductive metal material 118 with the photoresist layer 114 being removed.

FIG. 11 is a vertical cross-sectional view of forming a second photoresist layer 120 surrounding the first conductive metal material 118 in an intermediate interconnect structure. Similarly, the second photoresist layer 120 is a light-sensitive material used in a photolithography process to form geometric patterns onto a surface. The second photoresist layer 120 may be a positive photoresist layer where in the instance the photoresist layer is exposed to light, the second photoresist layer 120 becomes soluble to allow the exposed areas to be washed away or a negative photoresist layer where in the instance the second photoresist layer 120 is exposed to light, the second photoresist layer 120 becomes insoluble and the unexposed areas are washed away. The second photoresist layer 120 may be formed of a resin, photoactive compound, and a solvent and optionally dyes for visual inspection or anti-oxidizing agents to enhance stability.

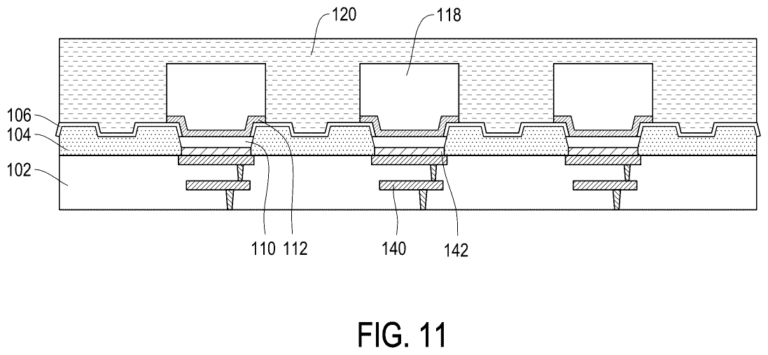

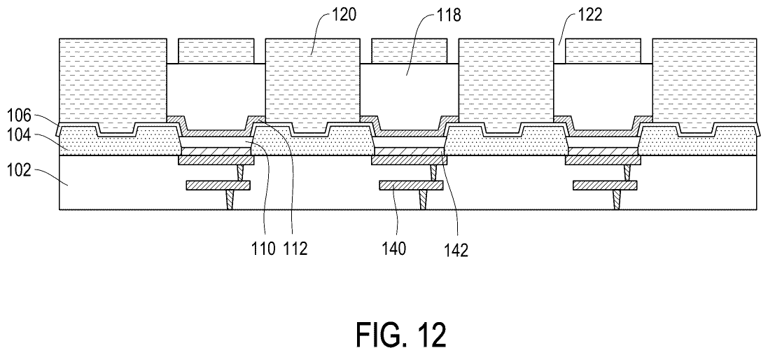

FIG. 12 is a vertical cross-sectional view of patterning and developing the second photoresist layer 120 in an intermediate interconnect structure. The second photoresist layer 120 may be exposed to light at a specific wavelength (e.g., UV light between 100 nm and 400 nm) through a mask with the desired pattern. In this embodiment and as shown in FIG. 12, the mask may include sections above each first conductive metal material 118 corresponding to the ring cavities 122 within the second photoresist layer 120. The chemical structure of the second photoresist layer 120 may be altered in areas exposed to the light beams. The second photoresist layer 120 may then be developed using a chemical solution which either removes the exposed or unexposed areas based on the type of photoresist material used. For example, a positive photoresist material will wash away the exposed areas while a negative photoresist material will wash away the unexposed areas. The resulting structure includes ring cavities 122 in the second photoresist layer 120.

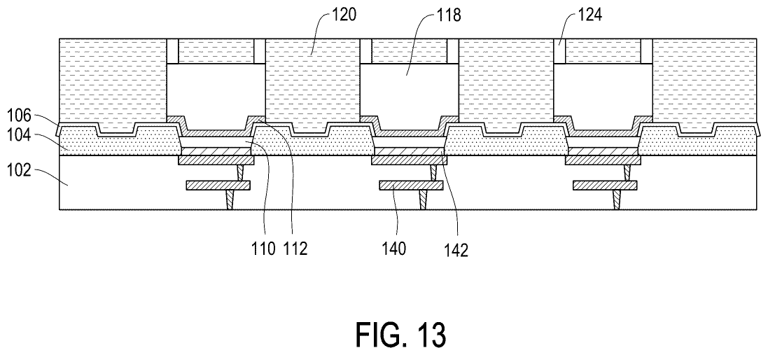

FIG. 13 is a vertical cross-sectional view of plating a ring conductive metal material in the ring cavities 122 to form a ring structure 124 in an intermediate interconnect structure. Initially, a thin layer of ring conductive metal material may be deposited onto the first metallic metal material 118. The ring conductive metal material may be copper, nickel, titanium, tungsten, gold, silver, or other appropriate conductive metal materials. The initial thin layer provides a conductive surface for electroplating. The intermediate interconnect structure may then be submerged in an electrolyte bath containing a solution of high-texture material ions, such as copper ions or copper sulfate. An electrical current may be applied causing the high-texture material ions to migrate and deposit onto the thin layer forming a thicker high-texture material layer. After electroplating, the surface may undergo planarization by being polished using a chemical-mechanical polishing process to remove excess ions and achieve a smooth planar surface. The resulting structure includes a ring structure 124 formed within the ring cavities 122.

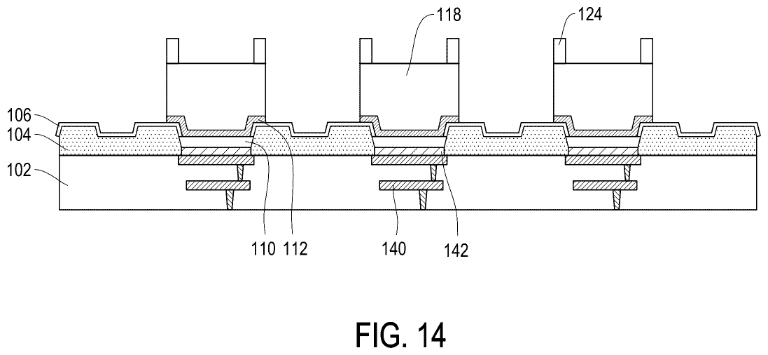

FIG. 14 is a vertical cross-sectional view of removing or stripping the second photoresist layer 120 leaving behind the ring structure 124 extending above the first conductive metal material 118 in an intermediate interconnect structure. The second photoresist layer 120 stripping process may include a wet stripping, a dry stripping, or a combination method. The resulting structure includes the ring structure 124 located above and extending from the first conductive metal material 118 and the second photoresist layer 120 being removed.

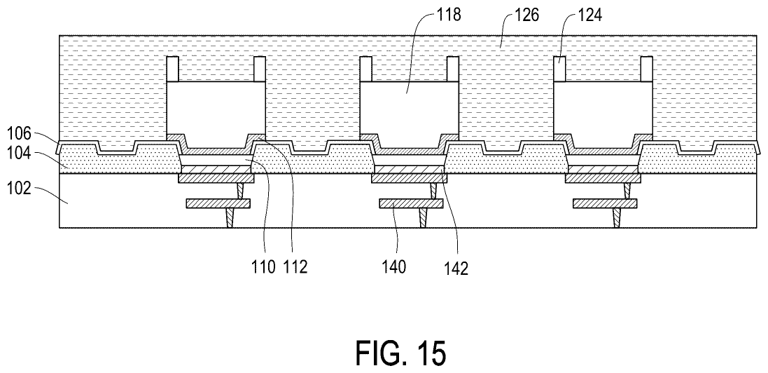

FIG. 15 is a vertical cross-sectional view of forming a third photoresist layer 126 surrounding the first conductive metal material 118 and ring structure 124 in an intermediate interconnect structure. The third photoresist layer 126 is a light-sensitive material used in a photolithography process to form geometric patterns onto a surface. The third photoresist layer 126 may be a positive photoresist layer or a negative photoresist layer. The third photoresist layer 126 may be formed of a resin, photoactive compound, and a solvent and optionally dyes for visual inspection or anti-oxidizing agents to enhance stability.

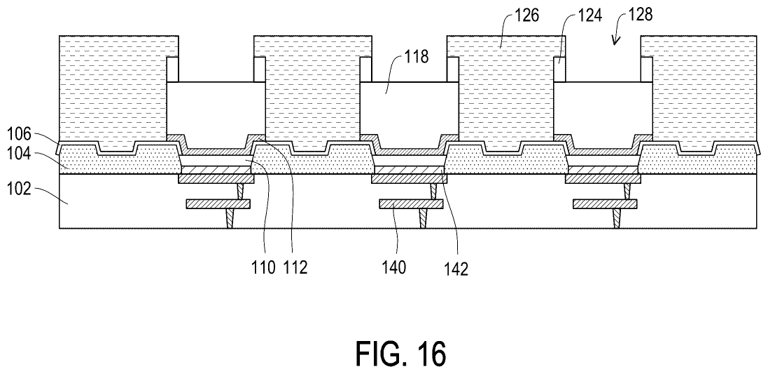

FIG. 16 is a vertical cross-sectional view of patterning and developing the third photoresist layer 126 in an intermediate interconnect structure. The third photoresist layer 126 may be exposed to light at a specific wavelength (e.g., UV light between 100 nm and 400 nm) through a mask with the desired pattern. The mask may include sections above each first conductive metal material 118 in between the ring structure 124 corresponding to the solder cavities 128 within the third photoresist layer 126. The chemical structure of the third photoresist layer 126 may be altered in areas exposed to the light beams. The structure may then be developed using a chemical solution which either removes the exposed or unexposed areas based on the type of photoresist material used. The resulting structure includes solder cavities 128 above the first conductive metal material 118 and surrounded by the ring structure 124 in the third photoresist layer 126.

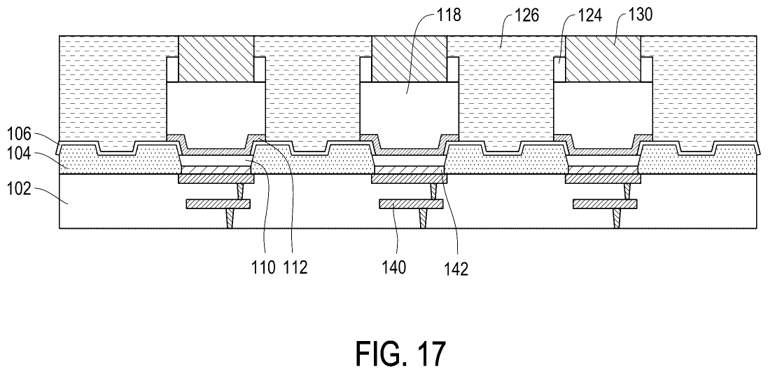

FIG. 17 is a vertical cross-sectional view of plating a solder material 130 in the solder cavities 124 in an intermediate interconnect structure. A thin layer of solder material 130 may be deposited onto the first metallic metal material 118 surrounded by the ring structure 124. The solder material may be lead free (LF) material or a copper lead free material (Cu/LF). The LF material may reduce environmental impact by eliminating lead materials that may accumulate in soil, water, or living organisms. As an example, the solder material may include an alloy containing at least one of tin, silver, copper, indium, and/or other appropriate metal materials. The initial thin layer provides a conductive surface for electroplating. The intermediate interconnect structure may then be submerged in an electrolyte bath containing a solution of high-texture material ions, such as copper ions or copper sulfate. An electrical current may be applied causing the high-texture material ions to migrate and deposit onto the thin layer forming a thicker high-texture material layer. After electroplating, the surface may undergo planarization by being polished using a chemical-mechanical polishing process to remove excess ions and achieve a smooth planar surface. The resulting structure includes a solder material 130 formed within the solder cavities 128.

FIG. 18 is a vertical cross-sectional view of removing or stripping the third photoresist layer 130 leaving behind the interconnect structure 150. The third photoresist layer 126 stripping process may include a wet stripping, a dry stripping, or a combination method. The resulting structure includes the solder portion 130 located above the first conductive metal material 118 and surrounded by the ring structure 124 forming the interconnect structure 150. The ring structures 124 may have a thickness between about 1 μm to about 10 μm. Such dimensions may provide sufficient barriers to retain the solder during the re-flow process, but also maintain the individual interconnect structures 150 such that the overall area occupied by the interconnect structures 150 are not increased.

FIGS. 1 through 18 illustrate a first photoresist layer 114 (FIG. 7), a second photoresist layer 120 (FIG. 11) and a third photoresist layer 126 (FIG. 15). The multiple photoresist layers may further prevent solder wetting. However, alternative embodiments may omit removing the various photoresist layers between formation steps and may simply reapply and pattern the existing photoresist layer. For example, the first photoresist layer 114 may be patterned to form the bump cavities 116, then the second photoresist layer 120 may be applied above the first photoresist layer 114 and patterned the ring cavities 122, and then the third photoresist layer 126 may be formed above the second photoresist layer 120 and patterned to form the solder cavities 128. Therefore, the photoresist layers may be formed above one another without removing the photoresist layers between cavity formations.

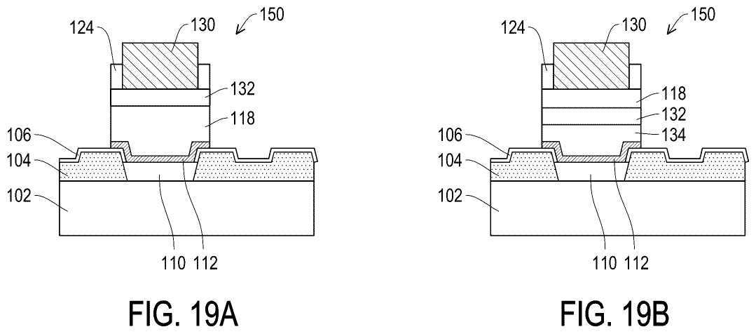

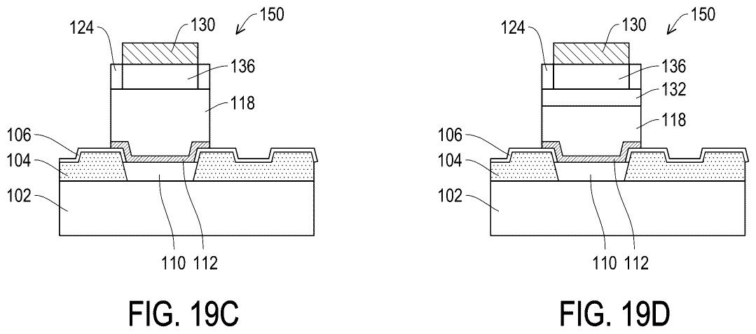

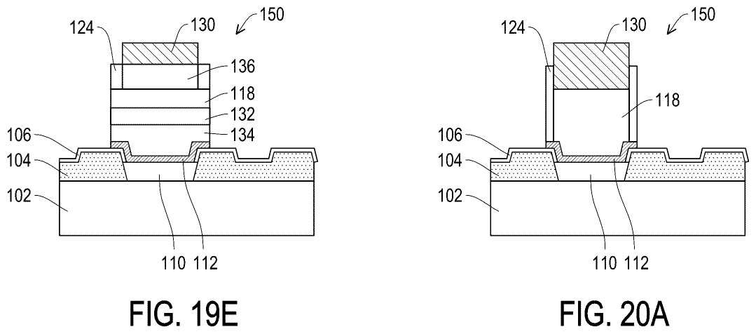

FIGS. 19A-19E illustrate vertical cross-sectional views of alternative interconnect structures 150. The interconnect structures 150 may have a pitch size of between about 1 μm to about 100 μm. The ring structure 124 shown in FIGS. 18 and 19A-19E is particularly useful when the spacing between the interconnect structures 150 is smaller and more difficult to locate during the photoresist process. In this instance, the configuration of the ring structure 124 minimizes the amount of space that is utilized by the interconnect structures 150.

FIG. 19A illustrates an alternative interconnect structure 150 that includes a second conductive metal material 132. The second conductive metal material 132 may be formed of copper, nickel, tungsten, titanium, silver, gold, or other appropriate conductive metal materials. In an embodiment, the ring structure 124 and the second conductive metal material 132 may be formed of the same conductive metal material. As shown in FIG. 19A, the second conductive metal material 132 may be located above the first conductive metal material 118. The solder bump 130 may be located above the second conductive metal material 132 and surrounded by the ring structure 124.

The addition of the second conductive metal material 132 may improve the ability of anti-wetting to the interconnect structure 150 compared to using only the first conductive metal material 118. For example, the first conductive metal material 118 may be chosen based on conductive properties, while the second conductive metal material 132 may be chosen based on anti-wetting properties. Therefore, by using two different conductive metal materials, a balance may be achieved between conductivity, wetting, and cost of the materials.

For example, the first conductive metal material 118 may be formed of copper due to its electrical conductivity and mechanical properties. However, copper is susceptible to wetting due to its surface properties. More specifically, copper readily oxidizes and therefore forms a layer of copper oxide on the surface which is prone to wetting. Additionally, copper has an affinity for water molecules, which additionally promotes wetting. Therefore, choosing a second conductive metal material 132, such as nickel, may prevent wetting. Following this example, nickel may act as a barrier layer preventing copper diffusing into the solder material 130. Additionally, nickel is less prone to oxidation compared to copper and therefore inhibits the flow of solder resulting in less wetting. Further, nickel has a higher surface energy compared to copper and therefore promotes adhesion and spreading of the solder material. As a result, by choosing a first conductive metal material 118 based on conductive properties and a second conductive metal material 132 based on anti-wetting properties, a balance between a proper electrical connection and avoiding solder material 130 wetting may be achieved.

FIG. 19B illustrates an alternative interconnect structure 150 that includes a second conductive metal material 132 and a third conductive metal material 134. As shown in FIG. 19B, the third conductive metal material 134 is located below the second conductive metal material 132 which is located below the first conductive metal material 118. In an embodiment, the first conductive metal material 118 and the third conductive metal material 134 may be formed of the same material and the second conductive metal material 132 and the ring structure 124 may be formed of the same material. The solder bump 130 may be located above the first conductive metal material 118 and surrounded by the ring structure 124. Similarly, the addition of the second conductive metal material 132 and third conductive metal material 134 may improve the ability of anti-wetting to the interconnect structure 150 compared to using only the first conductive metal material 118 or the first conductive metal material 118 and the second conductive metal material 132.

FIG. 19C illustrates an alternative interconnect structure 150 that includes a fourth conductive metal material 136 located above the first conductive metal material 118. In an embodiment, the fourth conductive metal material 136 may be formed of the same conductive metal material as the first conductive metal material 118. As shown in FIG. 19C, the fourth conductive metal material 136 is located above the first conductive metal material 118 and surrounded by the ring structure 124. The solder material 130 may be located above the fourth conductive metal material 136. The use of the first conductive material 118 and the fourth conductive material 136 formed of the same material decreases cost of the overall interconnect structure 150. Additionally, having the fourth conductive metal material 136 surrounded by the ring structure 124 reduces the amount of solder material 130 used in the interconnect structure 150. Reducing the amount of solder material 130 may mitigate against bump bridge as there may be less solder to achieve a bump bridge between interconnect structures.

FIG. 19D illustrates an alternative interconnect structure 150 that includes a fourth conductive metal material 136 located above a second conductive metal material 132. The second conductive metal material 132 may be located above the first conductive metal material 118. In an embodiment, the second conductive metal material 132 is formed of the same material as the ring structure 124 and the fourth conductive metal material 136 is formed of the same conductive metal material as the first conductive metal material 118. As shown in FIG. 19D, the fourth conductive metal material 136 may be surrounded by the ring structure 124. The solder material 130 may be located above the fourth conductive metal material 136. The addition of the second conductive metal material 132 may improve the ability of anti-wetting to the interconnect structure 150. Additionally, having the fourth conductive metal material 136 surrounded by the ring structure 124 may reduce the amount of solder material 130 used in the interconnect structure 150.

FIG. 19E illustrates an alternative interconnect structure 150 that includes a fourth conductive metal material 136 located above the first conductive metal material 118. Further, the first conductive metal material 118 may be located above a second conductive metal material 132 which is located above a third conductive metal material 134. In an embodiment, the first conductive metal material 118, the third conductive metal material 134, and the fourth conductive metal material 136 may be formed of the same conductive metal material. Additionally, in an embodiment, the second conductive metal material 132 may be formed of the same material as the ring structure 124. As shown in FIG. 19E, the fourth conductive metal material 136 may be located above the first conductive metal material 118 and surrounded by the ring structure 124. The solder material 130 may be located above the fourth conductive metal material 136. The addition of the second conductive metal material 132 and the third conductive metal material 134 may improve the ability of anti-wetting to the interconnect structure 150 compared to using only a first conductive metal material 118 or a first conductive metal material 118 and a second conductive metal material 132. Additionally, having the fourth conductive metal material 136 surrounded by the ring structure 124 reduces the amount of solder material 130 used in the interconnect structure 150.

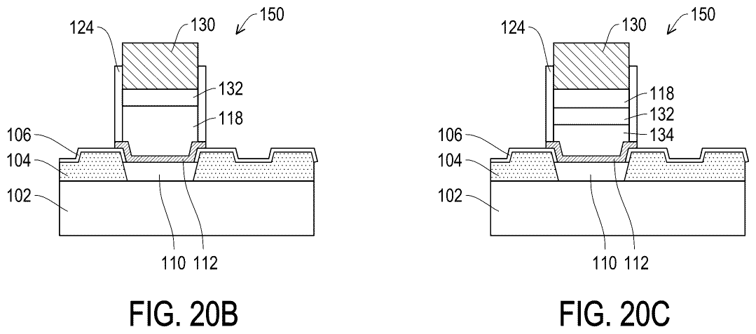

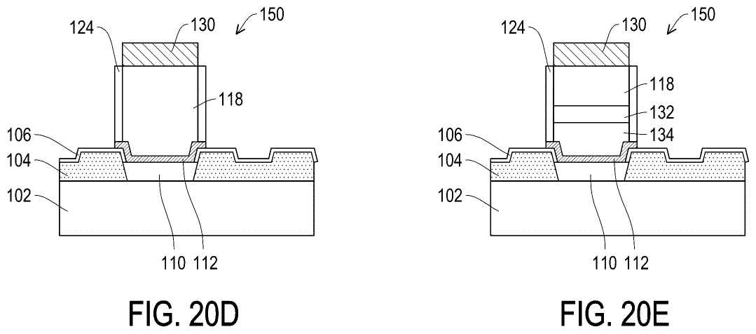

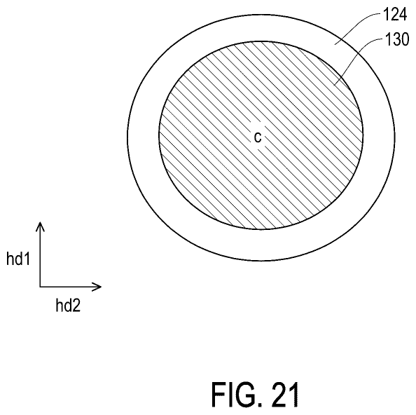

FIGS. 20A through 20E illustrate vertical cross-sectional views of alternative interconnect structures 150 in an alternative ring structure 124. In more detail, the ring structure 124 illustrated in FIG. 20A through E attaches to the seed layer 112 and fully surrounds the interconnect structure 150. In these examples, the ring structure 124 is particularly useful when the spacing between the interconnect structures 150 is larger and therefore easier to locate during the photoresist process. In this instance, the ring structure 124 takes up more space in the final interconnect structure 150.

FIG. 20A illustrates an alternative interconnect structure 150 that includes a first conductive metal material 118. Additionally, the ring structure 124 extends above and surrounds the first conductive metal material 118. The solder bump 130 may be located above the second conductive metal material 132 and surrounded by the ring structure 124. The use of the first conductive metal material 118 lowers the overall cost of forming the structure 150.

FIG. 20B illustrates an alternative interconnect structure 150 that includes a second conductive metal material 132. The second conductive metal material 132 may be formed of copper, nickel, tungsten, titanium, silver, gold, or other appropriate conductive metal materials. In an embodiment, the ring structure 124 and the second conductive metal material 132 may be formed of the same conductive metal material. As shown in FIG. 20A, the second conductive metal material 132 may be located above the first conductive metal material 118. The solder bump 130 may be located above the second conductive metal material 132. The ring structure 124 may be connected to the seed layer 112 and surround the first conductive material 118, the second conductive metal material 132, and a portion of the solder material 130. The addition of the second conductive metal material 132 may improve the ability of anti-wetting to the interconnect structure 150 compared to using only the first conductive metal material 118.

FIG. 20C illustrates an alternative interconnect structure 150 that includes a second conductive metal material 132 and a third conductive metal material 134. As shown in FIG. 20C, the third conductive metal material 134 is located below the second conductive metal material 132 which is located below the first conductive metal material 118. In an embodiment, the first conductive metal material 118 and the third conductive metal material 134 are formed of the same material and the second conductive metal material 132 and the ring structure 124 is formed of the same material. The solder bump 130 may be located above the first conductive metal material 118. The ring structure 124 may be connected to the seed layer 112 and surround the first conductive material 118, the second conductive metal material 132, and a portion of the solder material 130. Similarly, the addition of the second conductive metal material 132 and third conductive metal material 134 may improve the ability of anti-wetting to the interconnect structure 150 compared to using only the first conductive metal material 118 or the first conductive metal material 118 and the second conductive metal material 132.

FIG. 20D illustrates an alternative interconnect structure 150 that includes a first conductive metal material 118. The top surface of the first conductive metal material 118 may be planar with the ring structure 124. In an embodiment, the ring structure 124 fully surrounds the first conductive metal material 118. The solder material 130 may be located above the first conductive metal material 136. The use of the first conductive metal material 118 may lower the overall cost of forming the interconnect structure 150. Additionally, having the first conductive metal material 118 surrounded planar with the ring structure 124 may reduce the amount of solder material 130 used in the interconnect structure 150.

FIG. 20E illustrates an alternative interconnect structure 150 that includes a second conductive metal material 132 and a third conductive metal material 134. As shown in FIG. 20E, the third conductive metal material 134 is located below the second conductive metal material 132 which is located below the first conductive metal material 118. In an embodiment, the first conductive metal material 118 and the third conductive metal material 134 are formed of the same material and the second conductive metal material 132 and the ring structure 124 is formed of the same material. The top surface of the first conductive metal material 118 may be planar with the ring structure 124. The solder bump 130 may be located above the first conductive metal material 118. The ring structure 124 may fully surround the first conductive metal material 118, the second conductive metal material 132, and the third conductive metal material 134. Similarly, the addition of the second conductive metal material 132 and third conductive metal material 134 may improve the ability of anti-wetting to the interconnect structure 150 compared to using only the first conductive metal material 118 or the first conductive metal material 118 and the second conductive metal material 132. Additionally, having the first conductive metal material 118 surrounded planar with the ring structure 124 may reduce the amount of solder material 130 used in the interconnect structure 150.

FIG. 21 illustrates a top view of the ring structure 124 surrounding the solder material 130. As shown, the ring structure 124 may be substantially circular and surround the solder material 130. In alternative embodiments, the ring structure 124 may have a square, oval, or other shape based on the interconnect structure 150 shape. For example, in instances in which the interconnect structure 150 has an oval cross-sectional shape, the ring structure may also have an oval cross-sectional shape. Because the ring structure 124 surrounds the solder material 130, the ring structure 124 contains the solder material 130 during the reflow process. Therefore, the ring structure 124 is able to mitigate against bump bridging and bump tilting by containing the solder material 130 during the reflow process.

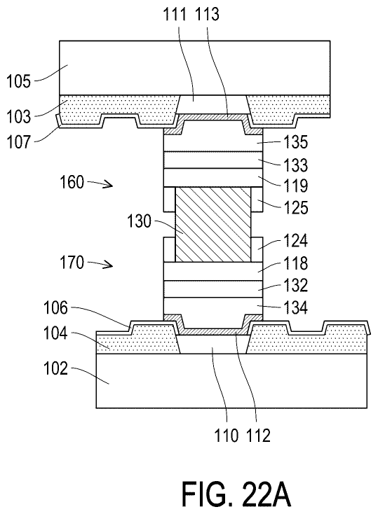

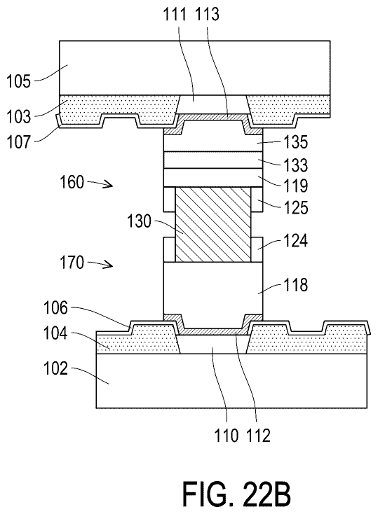

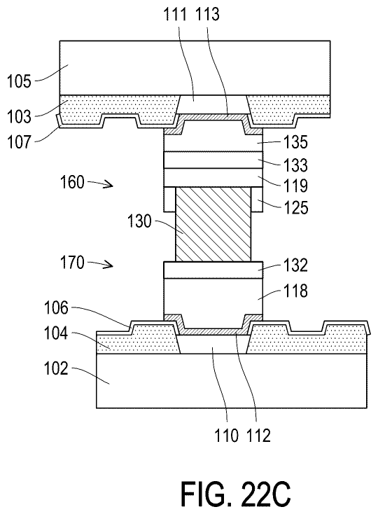

FIGS. 22A through 22C illustrate example cross-sectional views of a bottom bump 150 with a interconnect structure and a top interconnect structure 160, or a top bump 160, with a second scheme. The bottom interconnect structure 170, or the bottom bump 170, may be connected to a substrate 102 with a passivation layer 104, a dielectric layer 106, UBM structure 110 and seed layer 112. The top interconnect structure 160 may be connected to a semiconductor die 105 with a passivation layer 103, dielectric layer 107, UBM structure 111, and seed layer 113. The top interconnect structure 160 may include a first conductive metal material 119, second conductive metal material 133, and/or a third conductive metal material 135.

In some embodiments, as shown in FIG. 22A, the top interconnect structure 160 may have the same interconnect structure as the bottom interconnect structure 170. In alternative embodiments, as shown in FIGS. 22B and 22C, the top interconnect structure 160 may have a different interconnect structure as the bottom interconnect structure 170. In some embodiments, both the top interconnect structure 160 and the bottom interconnect structure 170 include a ring structure 124/125. In alternative embodiments, only the top interconnect structure 160 or the bottom interconnect structure 170 includes a ring structure 125 or 124. The ring structure 124/125 partially surrounds the solder material 130 therefore preventing bump bridging and bump tilting. By preventing bump bridging and bump tilting, the ring structures 124/125 improves reliability and performance of the package while maintaining appropriate electrical connection between the substrate 102 and the semiconductor die 105.

While various embodiments are shown in FIGS. 22A through 22C, other interconnect structure shown in FIGS. 19A-19E and 20A-20E may be used in the top interconnect structure 160 and the bottom interconnect structure 170. Therefore, various combinations of interconnect structure may be contemplated within the scope of this disclosure.

The following discussion now refers to a number of methods and method acts. Although the method steps are discussed in specific orders or are illustrated in a flow chart as being performed in a particular order, no order is required unless expressly stated or required because a step is dependent on another step being completed prior to the step being performed.

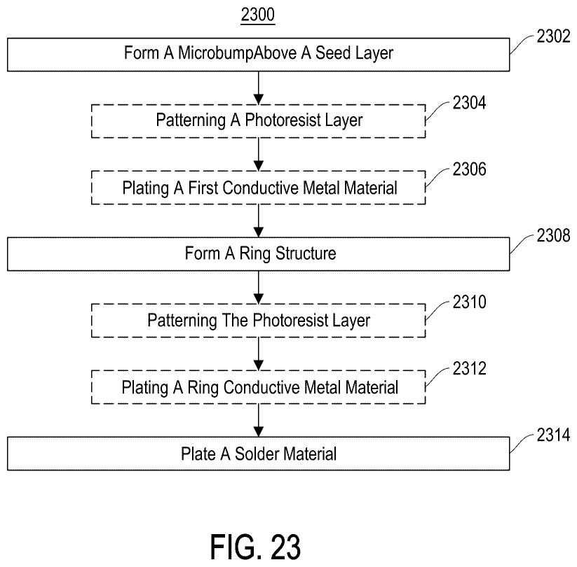

Embodiments are now described in connection with FIG. 23, which illustrates a flow diagram of example method 2300 for forming a semiconductor device according to an embodiment of the present disclosure. In an embodiment, step 2202 comprises forming an interconnect structure above a seed layer. Referring to FIGS. 6, 18, 19A-19C, and 20A-20E, in step 2302 of method 2300, the interconnect structure 150 may be formed above the seed layer 112. The seed layer 112 may be deposited above a dielectric layer 106 and a UBM structure 110. The seed layer 112 may be formed of copper and titanium.

Steps 2304 and 2306 describe sub-steps of forming the interconnect structure 150 above the seed layer 112. In an embodiment method 2300, step 2304 optionally comprises patterning a photoresist layer 114 to form a bump cavity 116. Referring to FIGS. 8 and 23, in step 2306 of method 2300, the bump cavity 116 may expose the seed layer 112 located above the UBM structure 110.

In an embodiment method, step 2306 comprises plating a first conductive metal material 118 within the bump cavity 116. Referring to FIGS. 9, 18, 19A-19E, 20A-20E, and 23, in step 2306 of method 2300, the first conductive metal material 118 may be plated above the seed layer 112 in the bump cavity 116. In some embodiments, first conductive metal material 118 may be formed of copper, tungsten, titanium, silver, gold, or other appropriate conductive metal materials. Optionally, the photoresist layer 114 may be removed or stripped after plating the first conductive metal material 118.

In alternative embodiments, a second conductive metal material 132, a third conductive metal material 134, and/or a fourth conductive metal material 136 may be plated in the bump cavity 116. In some embodiments, the second conductive metal material 134 is located below the first conductive metal material 118. In some embodiments, the third conductive metal material 136 is located below the second conductive metal material 134. In some embodiments, the fourth conductive metal material 136 is located above the first conductive metal material 118. In an embodiment, the first conductive metal material 118, the third conductive metal material 134, and the fourth conductive metal material 136 are formed of the same conductive metal material. In an embodiment, the second conductive metal material 132 is formed of the same material as the ring structure 124.

In an embodiment method, step 2308 comprises forming a ring structure 124 on the interconnect structure. Steps 2310 and 2312 describe sub-steps of forming the ring structure 124. In an embodiment, step 2310 comprises patterning the photoresist layer 120 to form a ring cavity 122. Referring to FIGS. 12 and 23, in step 2310 of method 2300, the second photoresist layer 120 may be patterned to form ring cavities 122.

In an embodiment method, step 2312 comprises plating a ring conductive metal material in the ring cavity 122 to form a ring structure 124. Referring to FIGS. 13, 18, 19A-19E, 20A-20E, and 23, in step 2312 of method 2300, the ring conductive metal material may be plated within the ring cavity 122 to form the ring structure 124. In some embodiments, the ring structure 124 extends above the first conductive metal material 118. In an alternative embodiment, the ring structure 124 connects to the seed layer 112 and surrounds the first conductive metal material 118.

In an embodiment method, step 2314 comprises plating a solder material partially surrounded by the ring structure. Referring to FIGS. 14, 17, and 23, in step 2314 of method 2300, the solder material 130 may be plated above the first conductive metal material 118.

Referring to all drawings and according to various embodiments of the present disclosure, a semiconductor device including a first interconnect structure on a first semiconductor substrate, wherein the first interconnect structure comprises a first conductive metal material 118; and a ring structure 124 extending above the first conductive metal material 118.

In some embodiments, the semiconductor device further includes a second conductive metal material 132 formed below the first conductive material 118, wherein the first conductive metal material 118 is formed of a different material than the first conductive metal material 118. In some embodiments, the semiconductor device further includes a third conductive metal 134 material formed below the second conductive material 132, wherein the third conductive metal 134 material is formed of a different material than the second conductive metal material 132. In some embodiments, the ring structure 124 is formed of the same material as the second conductive metal material 132. In some embodiments, the semiconductor device further includes a solder material 130 located above the first conductive metal material 118 and surrounded by the ring structure 124. In some embodiments, the semiconductor device further includes a second interconnect structure 170 where the solder material 130 is located between the first interconnect structure 160 and the second interconnect structure 170. In some embodiments, the semiconductor device further includes a fourth conductive metal material 136, wherein the ring structure 124 surrounds the fourth conductive metal material 136.

In an alternative embodiment, a semiconductor device includes a first conductive metal material 118 and a ring structure 124, wherein the ring structure surrounds the first conductive metal material 118.

In some embodiments, the semiconductor device further includes a second conductive metal material 132 formed below the first conductive material 118 and the ring structure 124 surrounds the second conductive metal material 132, wherein the second conductive metal material 132 is formed of a different material than the first conductive metal material 118. In some embodiments, the semiconductor device further includes a third conductive metal material 134 formed below the second conductive material 132 and the ring structure 124 surrounds the third conductive metal material 134, wherein the third conductive metal material 134 is formed of a different material than the second conductive metal material 132. In some embodiments, the ring structure 124 is formed of the same material as the second conductive metal material 132. In some embodiments, the semiconductor device further includes a solder material 130 located above the first conductive metal material 118 and surrounded by the ring structure 124. In some embodiments, the semiconductor device further includes a second interconnect structure 170 where the solder material 130 is located between the first interconnect structure160 and the second interconnect structure 170. In some embodiments, the ring structure 124 surrounds the second conductive metal material 132 and the third conductive metal material 134.

In an alternative embodiment, a method 2200 for forming a semiconductor device includes forming a microbump 150 above a seed layer 112, forming a ring structure 124 on the bump 150, and plating a solder material 130 partially surrounded by the ring structure 124..

In some embodiments, forming the bump 150 above the seed layer 112 further includes patterning a photoresist layer 114 to form a bump cavity 116, plating a first conductive metal material 118 within the bump cavity 116. In some embodiments, the method 2200 further includes plating a second conductive metal material 132 within the bump cavity 116, wherein the first conductive metal material 118 is plated above the second conductive metal material 132. In some embodiments, the method 2200 further includes plating a third conductive metal material 134 within the bump cavity 116, wherein the second conductive metal material 132 is plated above the third conductive metal material 134. In some embodiments, forming the ring structure 124 further includes patterning the photoresist layer 120 to form a ring cavity 122. plating a ring conductive metal material in the ring cavity 122 to form the ring structure 124. In some embodiments, the ring cavity 122 is patterned to extend above the bump 150. In some embodiments, the ring cavity 122 is patterned to surround the bump 150. In some embodiments, the method further includes forming a second bump 160 where the solder material 130 is located between the bump 160 and the second bump 170.

Various embodiments disclosed herein may provide various advantages and improvements. For example, various embodiments disclosed herein may include a ring structure that surrounds a portion of the solder. Therefore, various embodiments disclosed herein may prevent bump bridging by ensuring the individual microbumps stay separated during the reflow process. By preventing bump bridging, various embodiments improve reliability tests of the semiconductor device, such as a HTS test. Additionally, various embodiments disclosed herein prevent bump tilting by ensuring the microbumps form perpendicular to the substrate or interposer during the reflow process. By preventing bump tilting, various embodiments improve mechanical strength of the microbumps to reduce mechanical failures therefore improving performance and reliability of the semiconductor device. Various embodiments disclosed herein may further improve electrical connection between the substrate and the semiconductor dies through the bumps by improving the interconnect structure formed during the reflow process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first interconnect structure on a first semiconductor substrate, wherein the first interconnect structure comprises a first conductive metal material and a ring structure extending above the first conductive metal material.

2. The semiconductor device of claim 1, further comprising a second conductive metal material formed below the first conductive material, wherein the first conductive metal material is formed of a material based on conductive properties and the second conductive metal material is formed of a material based on anti-wetting properties.

3. The semiconductor device of claim 2, further comprising a third conductive metal material formed below the second conductive material, wherein the third conductive metal material is formed of a material based on conductive properties.

4. The semiconductor device of claim 1, wherein the ring structure is formed of the same material as the second conductive metal material.

5. The semiconductor device of claim 1, further comprising a solder material located above the first conductive metal material and surrounded by the ring structure.

6. The semiconductor device of claim 1, further comprising a second interconnect structure wherein the solder material is located between the first interconnect structure and the second interconnect structure.

7. The semiconductor device of claim 1, further comprising a fourth conductive metal material, wherein the ring structure surrounds the fourth conductive metal material.

8. A semiconductor device, comprising:
a first interconnect structure formed overlying a first semiconductor substrate, wherein the first interconnect structure comprises a first conductive metal material and a ring structure, wherein the ring structure surrounds a portion of the first conductive metal material.

9. The semiconductor device of claim 8, further comprising a second conductive metal material formed below the first conductive material and the ring structure surrounds the second conductive metal material, wherein the first conductive metal material is formed of a material based on conductive properties and the second conductive metal material is formed of a material based on anti-wetting properties.

10. The semiconductor device of claim 9, further comprising a third conductive metal material formed below the second conductive material and the ring structure surrounds the third conductive metal material, wherein the third conductive metal material is formed of a material based on conductive properties.

11. The semiconductor device of claim 8, wherein the ring structure is formed of the same material as the second conductive metal material.

12. The semiconductor device of claim 8, further comprising a solder material located above the first conductive material and surrounded by the ring structure.

13. The semiconductor device of claim 12, further comprising a second interconnect structure, wherein the solder material is located between the first interconnect structure and the second interconnect structure.

14. The semiconductor device of claim 8, wherein the ring structure surrounds the second conductive metal material and the third conductive metal material.

15. A method for forming a semiconductor device, comprising:
forming a bump above a seed layer;
forming a ring structure on the bump; and
plating a solder material partially surrounded by the ring structure.

16. The method of claim 15, wherein forming the bump above the seed layer further comprises:
patterning a photoresist layer above the seed layer to form a bump cavity; and
plating a first conductive metal material within the bump cavity.

17. The method of claim 16, further comprising plating a second conductive metal material within the bump cavity, wherein the first conductive metal material is plated above the second conductive metal material.

18. The method of claim 17, further comprising plating a third conductive metal material within the bump cavity, wherein the second conductive metal material is plated above the third conductive metal material.

19. The method of claim 15, wherein forming the ring structure further comprises:
patterning a photoresist layer to form a ring cavity, wherein the ring cavity is patterned to extend above the bump or to surround the bump; and
plating a ring conductive metal material in the ring cavity to form a ring structure.

20. The method of claim 15, further comprising forming a second bump, wherein the solder material is located between the bump and the second bump.
